(19) United States
(12) Patent Application Publication
(10) Pub. No.: US 2026/0095135 A1
(43) Pub. Date: Apr. 2, 2026

(54) SENSING OF SIGNALS WITH COMMON MODE VARIATION

(71) Applicant: Cirrus Logic International Semiconductor Ltd., Edinburgh (GB)

(72) Inventors: Zhaohui HE, Austin, TX (US); Prashanth DRAKSHAPALLI, Austin, TX (US); Lingli ZHANG, Austin, TX (US); John L. MELANSON, Austin, TX (US)

(73) Assignee: Cirrus Logic International Semiconductor Ltd., Edinburgh (GB)

(21) Appl. No.: 19/340,151

(22) Filed: Sep. 25, 2025

Related U.S. Application Data
(60) Provisional application No. 63/700,052, filed on Sep. 27, 2024.

(51) Int. Cl. H03F 3/45; H03K 17/16; H03K 17/284

(52) U.S. Cl. CPC H03F 3/45475; H03F 3/45941; H03K 17/165; H03K 17/284; H03F 2200/462; H03F 2200/481; H03F 2203/45174

(57) ABSTRACT

This application relates to sensing of signals with a common-mode variation. Embodiments describe a switching driver circuit with a modulator configured to control modulation of an output node between different switching voltages and a current sensor configured to sense a voltage drop across a sense resistor connected in series with the output node. The current sensor performs sensing during a first time window that occurs at regular intervals and the modulator avoids any transition in switching voltage at the first output node during the first time window. Embodiments also describe a sensing circuit for sensing a differential voltage with a common-mode variation which has a first sensing portion implemented to provide a floating voltage domain and a second sensing portion implemented to provide a static voltage domain. At least one switched capacitor provides a boundary between the voltage domains and is switched to transfer charge between the voltage domains.

### TECHNICAL FIELD

The field of representative embodiments of this disclosure relates to methods, apparatus and/or implementations concerning or relating to sensing of signals with common-mode variation. Embodiments may be particularly suited for output current sensing for switching drivers, especially for multi-level switching drivers.

### BACKGROUND

Switching drivers, e.g. class-D drivers and the like, also referred to as switching amplifiers or switched-mode amplifiers, are used in a variety of applications. In a switching driver, at least one output node is modulated between different switching voltages over the course of a switching cycle. The duty-cycle of modulation is controlled so that the average voltage at the output node, over the course of the switching cycle, has a desired value.

It is desirable, in such switching drivers, to monitor the output current and typically this is performed by monitoring the voltage across a sense resistor in the output path, i.e. connected in series with the output node. Voltages on either side of the sense resistor may be sensed, for example using a differential amplifier followed by an ADC (analog-to-digital converter).

One issue with such sensing is that the sensed voltages on either side of the sense resistor will be modulated together with the output node, resulting in a significant change in the common-mode voltage. The resistance of the sense resistor is typically low, so as to minimise resistive losses, and thus the differential voltage of interest across the sense resistor, due to the current through the sense resistor, is typically quite low compared to change in common-mode voltage. This can lead to a problem that mismatch in components of the current sensing circuitry, e.g. of the differential amplifier, can lead to common-mode to differential-mode conversion and any such unwanted differential component may be relatively significant compared to actual differential signal of interest.

For conventional two-level switching amplifiers, an output node may be modulated between just two switching voltages in use, e.g. between a defined high-side voltage VH and a defined low-side voltage VL, where the high-side and low-side voltage are selected to be sufficient for the entire desired voltage range at that output node. However, multi-level switching drivers have been proposed for some applications, where the switching voltages for modulation of the output node may be varied with signal level. Such multi-level switching drivers, also referred to as multi-level converters (MLCs) can generate different switching ranges at the output node(s), which can be adjusted based on the output signal to be generated. Examples of such MLC systems can be found in U.S. Pat. No. 11,791,816 and US Patent Application Publication No. 2022/0376618, the contents of which are incorporated by reference herein.

For instance, for a first range of output voltage, the output node may be modulated between a pair of voltages, say, V1 and V2, but for a different range of output voltage the output node may be modulated between a different pair of voltages, say V2 and V3. For such a multilevel switching amplifier, the common-mode voltage for the current sensing thus not only varies within a switching cycle of the switching driver but also the relevant common-mode voltage has a signal dependent variation of the band of interest, and the change in voltage ranges at the output node(s) may result in a large common-mode voltage change.

Sudden large changes in common-mode voltage can create challenges for the current sensing circuitry and, as the output of such an MLC switching driver has multiple signal dependent common mode levels, a high Common-Mode Rejection Ratio (or CMRR) is desirable to reduce signal dependent common mode conversion to fully differential signal.

### SUMMARY

Embodiments of the present disclosure relate to sensing of signals which experience a significant variation in common-mode voltage which address at least some of the above-mentioned issues.

According to an aspect of the disclosure there is provided a switching driver circuit comprising a modulator configured to control a switching output stage to modulate a first output node between different switching voltages with a controlled duty-cycle based on an input signal, and a current sensor configured to sense an output current through the first output node by sensing a voltage drop across a sense resistor connected in series with the first output node. The current sensor is operable to perform a first sensing operation during a first time window that occurs at regular intervals and the modulator is configured to control the switching output stage to avoid any transition in switching voltage at the first output node during said first time window.

In some examples, the current sensor may comprise first and second sensor input nodes connected on either side of the sense resistor to receive first and second sense voltages and first and second sampling capacitors. The current sensor may be configured to be operable in a sampling phase in which the first and second sampling capacitors are connected to be charged by the first and second sense voltages respectively. The first time window may correspond to at least an end period of said sampling phase.

The current sensor may be further configured to be operable in a transfer phase in which charge sampled onto the first and second sampling capacitors during the sampling phase is configured to be transferred to an integrator. The current sensor may be configured such that, during the transfer phase, the first and second sampling capacitors are connected to the second and first sense voltages respectively. The first time window may also comprise the transfer phase.

The first and second sampling capacitors may be configured to act as a boundary between a first voltage domain for sensing the first and second sense voltages and a second voltage domain for the integrator. The first voltage domain may be a floating voltage domain and the second voltage domain may be a static voltage domain.

The current sensor may be further configured to be operable in a pre-charging phase in which the first and second capacitors are each charged to a voltage indicative of a common-mode voltage of the first and second sense voltages. At least part of said pre-charging phase may be outside of said first time window such that a transition in switching voltage at the first output node can occur during the pre-charging phase.

In some examples, the current sensor may comprise a feedback arrangement comprising first and second feedback capacitors. The feedback arrangement may be configured to be operable in a sampling phase in which the first and second feedback capacitors are connected to be charged by first and second feedback voltages and a transfer phase in which the charge sampled onto the first and second feedback capacitors during the sampling phase is configured to be transferred to an integrator. The first time window may comprise at least one of said sampling and transfer phases.

In some examples, the modulator may be configured to determine an initial timing for a voltage transition at the first output node and to determine whether said initial timing falls within said first time window and, if so, to apply a timing shift to said initial timing to determine a new timing for the voltage transition that falls outside the first time window. The timing shift may be either of a timing advance or a timing delay. The modulator may be configured to carry any timing error arising from said timing shift in one modulator switching cycle into one or more subsequent modulator switch cycles.

The modulator may be further configured to control the switching output stage to modulate a second output node between different switching voltages with a controlled duty-cycle based on the input signal so as to drive a load connected between the first and second output nodes in a bridge-tied-load configuration. In this case, the modulator may be configured to determine an initial timing for a voltage transition at the second output node and to apply any timing shift determined for the voltage transition at the first output node as a timing shift for the voltage transition at the second output node.

In another aspect there is provided a sensing circuit for sensing a differential voltage between first and second sense voltages, wherein a common-mode voltage of the first and second sense voltages varies in use. The sensing circuit comprising a first sensing portion implemented to provide a first voltage domain which is a floating voltage domain and a second sensing portion implemented to provide a second voltage domain which is a static voltage domain referenced to a defined reference voltage. At least one switched capacitor is configured to provide a boundary between the first and second voltage domains and being switched to transfer charge between the first and second voltage domains.

The at least one switched capacitor may be configured as a sampling capacitor that can be switched to sample at least one of the first and second sense voltages. The at least one switched capacitor may comprise first and second sampling capacitors and the sensing circuit may be operable in each of a: a first phase in which the first and second sampling capacitors are each charged by a first domain voltage indicative of the common-mode voltage of the first and second sense voltages, a second phase in which the first and second sampling capacitors are charged by the first and second sense voltages respectively; and a third phase in which the first and second sampling capacitors are switched to transfer charge to said second sensing portion.

In some implementations, the first sensing portion may comprise gain circuitry for applying gain to the first and second sense voltages. The gain circuitry may comprise an integrator. The integrator may be configured as a continuous time integrator and the sensing circuit may comprise a discrete time feedback arrangement comprising said at least one switched capacitor.

In a yet further aspect there is provided a switching driver circuit comprising a modulator configured to control a switching output stage to modulate a first output node between different switching voltages with a controlled duty-cycle based on an input signal and an analog to digital converter configured to sample an output current through the first output node by sensing a voltage drop across a sense resistor connected in series with the first output node at defined sample periods. The modulator is configured to control the switching output stage to prevent voltage transitions at the first output node in time windows that include said sample periods.

In some examples, the analog to digital converter may comprise a first portion implemented in a first floating voltage domain and a second portion implemented in a second static voltage domain.

It should be noted that, unless expressly indicated to the contrary herein or otherwise clearly incompatible, then any feature described herein may be implemented in combination with any one or more other described features.

### BRIEF DESCRIPTION OF THE DRAWINGS

For a better understanding of examples of the present disclosure, and to show more clearly how the examples may be carried into effect, reference will now be made, by way of example only, to the following drawings in which:

FIG. 1 illustrates a conventional current sensing arrangement for a switching driver;

FIG. 2 illustrates the operation of a multi-level switching driver; and

FIG. 3 illustrates one example of how current sensing could be implemented for a switching driver;

FIG. 4 illustrates a sensing circuit with different voltage domains according to an embodiment;

FIG. 5 illustrates a timing diagram for the operation of the sensing circuit of FIG. 4;

FIG. 6 illustrates one example of how a switching driver may control edge transitions at an output node;

FIG. 7 illustrates a sensing circuit according to an embodiment with an anti-aliasing filter in the floating voltage domain and feedback in the ground referenced voltage domain;

FIG. 8 illustrates a sensing circuit according to another embodiment, with gain in the floating domain; and

FIG. 9 illustrates a sensing circuit according to another embodiment, with the transition between voltage domains provided by capacitors of the switched capacitor feedback loop.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

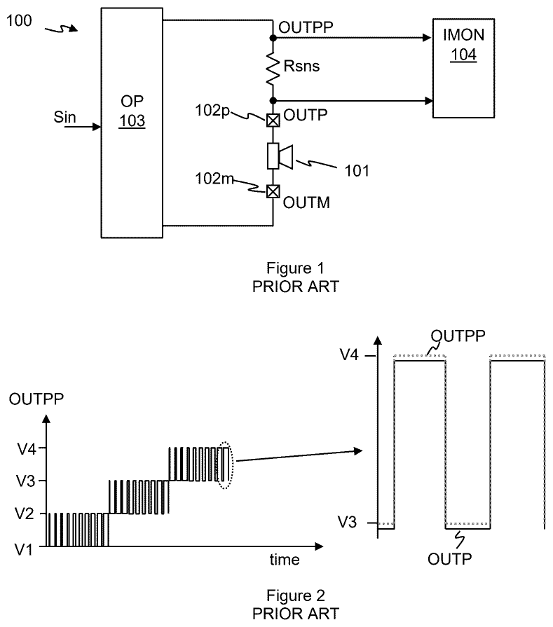

FIG. 1 illustrates generally an example of switching driver 100 for driving a load 101, which may, for example, be a transducer such a speaker or the like. The switching driver 100 of the example of FIG. 1 is configured to drive the load 101 in a bridge-tied-load (BTL) configuration and thus the load is connected between first and second output nodes 102p and 102m and an output stage 103 is configured to control modulation of each of the first and second output nodes 102p and 102m between respective switching voltages so as generate a desired differential drive voltage across the load 101, on average over the course of a switching cycle. It will be understood, however, that in some implementations the switching driver 100 could be implemented to drive the load 101 in a single-ended configuration will modulation of just one output node, say node 102p, with the other side of the load, e.g. node 102m, being held at a defined DC voltage.

The switching driver 100 includes some current monitoring circuitry configured to monitor the output current from the switching driver 100, i.e. the load current through the load 101. FIG. 1 illustrates that a sense resistor Rsns is connected in the output path to the load, in this example in series with the first output node 102p and the voltage drop across the sense resistor Rsns is used to provide an indication of the output current. Current monitoring circuitry 104 is used configured to monitor the voltages on either side of the sense resistor Rsns, denoted as OUTPP and OUTP, where (in this example) OUTP is the instantaneous voltage at the first output node 102p and OUTPP is the voltage on the other side of the sense resistor Rsns, which in this case the voltage output from the output stage 103. The voltage at the second output node 102n is denoted as OUTM.

In some cases, the output stage 103 may be implemented as a multilevel output stage which is operable to modulate each output node between different switching voltages where the switching voltages are varied with signal level of the input signal Sin (and hence the desired drive signal for the load) as illustrated in FIG. 2. FIG. 2 illustrates that initially the voltage OUTPP which is output from the output stage may be modulated between switching voltages V1 and V2 with a controlled duty-cycle so as to have a desired average voltage in the range V1 to V2. As the level of the input signal Sin changes, and hence the level of the desired drive voltage changes, the modulation of the voltage OUTPP switches to being modulated between V2 and V3 and then later to being modulated between V3 and V4. It will be understood that in a BTL configuration the voltages applied to the second output node 102m will also be modulated so as to generate a desired average differential voltage across the load.

FIG. 2 also illustrates in more detail how the voltage OUTP may vary with the modulation of the voltage OUTPP. In the example illustrated the voltage OUTP is lower (i.e. less positive or more negative in this example) than the voltage OUTPP due to the load current flowing through the sense resistor. However, as noted, the resistance of the sense resistor Rsns will typically be low and thus the voltage change across the sense resistor Rsns will be low. The modulation of the voltage OUTPP will thus lead to a consequential modulation in the voltage OUTP which is significantly greater than the voltage difference between OUTPP and OUTP which is of interest for current sensing. There is thus a large change in the common-mode voltage of the voltages OUTPP and OUTP compared to the differential component of these voltages and the common-mode modulation will vary with the switching voltages that OUTPP is modulated between and will thus vary with signal level. This can create challenges for the current sensing circuitry.

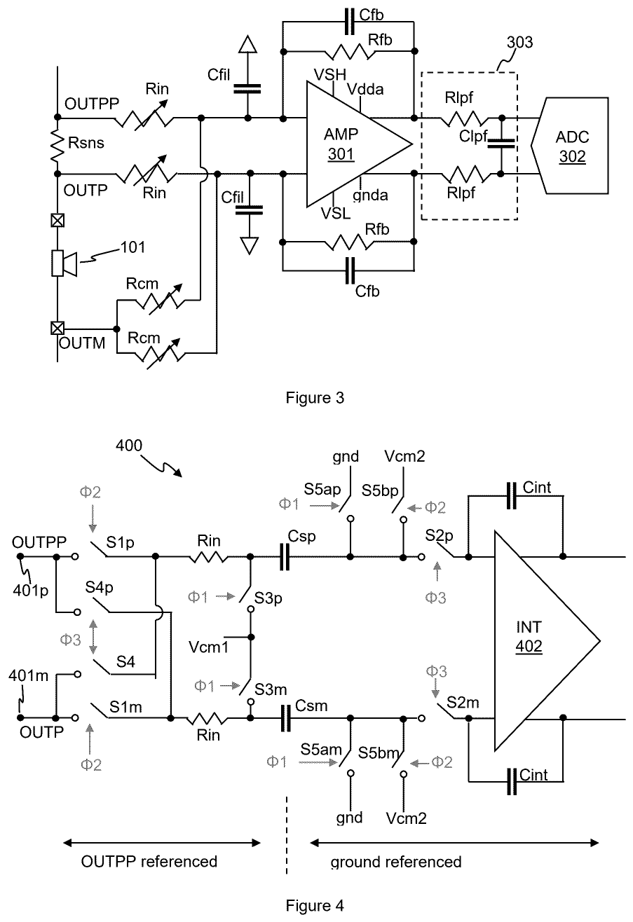

FIG. 3 illustrates one approach to current sensing that could be applied. FIG. 3 illustrates that the voltages OUTPP and OUTP could be supplied to respective inputs of differential-input differential-output amplifier 301. Input resistances Rin in the respective input paths for the differential amplifier 301 are configured, together with the respective amplifier feedback resistance Rfb and feedback capacitance Cfb to provide a desired voltage gain. The differential outputs of the amplifier 302 are supplied to a differential input ADC 302, in this example via a low-pass filter arrangement 303 that comprises resistance Rlpf and capacitance Clpf that could be configured as an anti-aliasing filter (AAF). The input stage of the amplifier 301 is powered by suitable voltage VSH and VSL which are set with respect to the range of expected input voltage and the output stage of the amplifier 301 is supplied with an amplifier supply Vdda and ground gnda. The amplifier 301 thus acts as a ground referenced analog front end (AFE).

As discussed previously, the differential voltage of interest across the sense resistor Rsns, i.e. OUTPP−OUTP, has a large variation in common-mode due to the modulation of OUTPP, and hence OUTP, which can create some challenges for sensing.

The example of FIG. 3 thus includes relatively large capacitances Cfil connected to the input paths for the AFE amplifier 301 to effectively provide filtering of this common-mode modulation. In addition, for the BTL configuration illustrated in the example of FIG. 3, respective paths from the second output node to the inputs of the amplifier 301 may be provided so that voltage OUTM is effectively applied to both inputs via resistances Rcm. The voltage OUTM may be modulated in the opposite fashion to the voltage OUTPP, i.e. when the voltage OUTPP is increased (to be more positive or less negative), the voltage OUTM may be decreased (to be less negative or more positive). Thus, applying the voltage OUTM to the inputs of the amplifier 301 can reduce the signal dependent variation in common-mode voltage. This does, however, almost double the input referred noise for the amplifier. The input referred noise is mainly governed by the size of the resistors Rin (and Rcm) and in general it is desirable to minimise noise where possible.

The input referred noise could be reduced by omitting the paths for the voltage OUTM and using a relatively small value for the resistors Rin. However, this would result in the full common-mode swing in OUTPP and OUTP being applied to the input of the AFE and the capacitances Cfil would have to be significantly larger to try to limit the common-mode swing at the amplifier virtual earth, which may not be practical. This could, therefore, result in a relatively large common-mode current through Rin and Rfb and any mismatch in at least these components could result in degraded THD (total harmonic distortion), PSSR (power supply rejection ratio) performance and voltage-to-current isolation.

Embodiments of the present disclosure thus apply a different approach for sensing of a differential voltage where there is a significant variation in a common-mode component. In at least some embodiments of the disclosure, the sensing system is provided with two voltage domains, a first floating voltage domain where the voltage(s) of interest is to be sensed, with a second, static, voltage domain referenced to a defined voltage, which may be ground, for conversion of the sensed signals into an output, such a suitable digital signal. In at least some embodiments, the boundary between the first and second voltage domains is provided by at least one capacitor which is configured to effectively block substantially any common-mode component from crossing from the first voltage domain to the second, whilst allowing the differential signal of interest to cross.

FIG. 4 illustrates one general example of sensing circuit 400 according to an embodiment. The sensing circuit 400 comprises first and second input nodes 401p and 401m for receiving differential input voltages, in this example the voltages OUTPP and OUTP respectively. The first input node 401p can be selectively connected to a first electrode of a first sampling capacitor Csp via switch S1p and the second input node 401p can be selectively connected to a first electrode of a second sampling capacitor Csm via switch S1m. The second terminals of the first and second sampling capacitors can be selectively connected to respective inputs of a differential amplifier 402 via respective switches S2p and S2m. The differential amplifier 402 is configured with capacitances Cint as an integrator.

In the example of FIG. 4, the first and second sampling capacitors Csp and Csm effectively define a boundary between a first voltage domain for the input voltages, which is referenced to a variable voltage and thus is effectively a floating voltage domain, and a second voltage domain which is reference to a defined voltage, for instance ground.

In the example of FIG. 4, the first and second sampling capacitors Csp and Csm are operated as sampling capacitors of a switched capacitor sensing circuit, e.g. a switched capacitor ADC (analog-to-digital converter), but also work as both common-mode blocking capacitors—for blocking the common-mode voltage of the first voltage domain from crossing the boundary—and AC coupling capacitors for allowing charge arising from the signal of interest to be sensed and transferred across the boundary to the integrator capacitor(s) of the second voltage domain.

The sensing circuit 400 includes switches S3p and S3m as part of the first voltage domain for selectively connecting the respective first terminals of the first and second sampling capacitors Csp and Csm to a first domain voltage Vcm1 indicative of the common-mode voltage of the voltages at the first and second input nodes 401p and 401m. In some implementations, the first domain voltage Vcm1 may be determined as being the average of the input voltages, e.g. as (OUTPP+OUTP)/2. However, for example of current sensing discussed with reference to FIG. 1, given the common-mode component of the input voltages is large compared to the differential voltage of interest, in some examples, one of the input voltages, for instance OUTPP may be used as domain voltage Vcm1

The sensing circuit 400 also comprises switches S4p and S4m in the first voltage domain for selectively connecting the respective first terminals of the first and second sampling capacitors Csp and Csm to the second and first input terminals 401m and 401p respectively. This allows for double sampling as will be discussed below.

The sensing circuit 400 of FIG. 4 further comprises switches S5ap and S5am for selectively connecting the respective second electrode of first and second sampling capacitors Csp and Csm to a reference voltage, in this example ground. FIG. 4 also illustrated switches S5bp and S5bm for selectively connecting the respective second electrode of first and second sampling capacitors Csp and Csm to a second domain voltage Vcm2 which defines a common-mode voltage for the signals of the second voltage domain. In some examples the second domain voltage Vcm2 may the same as the reference voltage to which switches S5ap and S5bp connected, e.g. may be ground, and in that case the functionality of switches S5ap and S5bp could be provided by a single switch (and likewise switches S5am and S5bm could be combined into a single switch).

The switching circuit may operate in three different phases. In a first phase, defined by a first timing signal φ1, switches S3p, S3m, S5ap and S5am are closed (with the other switches open) so as to charge each of the first and second sampling capacitors Csp and Csm to the first domain voltage Vcm1. This effectively pre-charges each of the first and second sampling capacitors Csp and Csm to the common-mode voltage of the input voltages.

In a second phase, defined by a second time signal ¢2, switches S1p, S1m, S5bp and S5bm are closed to sample the input voltages on the first and second sampling capacitors Csp and Csm (with reference to the defined second domain common-mode voltage Vcm2).

In the third phase, defined by a third timing signal φ3, switches S2p and S2m are closed to provide charge transfer and hence read-out of the sampled voltages. In the example of FIG. 4, switches S4p and S4m are also closed during the third phase, to connect the first electrodes of the first and second sampling capacitors to the opposite input voltage used for charging that sampling capacitor in the second phase (φ2). This provides double sampling of the input differential voltage of interest.

It will be understood, however, that the sensing circuit 400 could be implemented without double sampling, i.e. with single sampling, and in that case the first electrodes of the first and second sampling capacitors Csp and Csm could, for instance, be connected to one another and left floating during the third phase.

This operation, in the three phases, thus means that the first and second sampling capacitors Csp and Csm are pre-charged to the first domain voltage Vcm1 (which is substantially equal to the common-mode voltage of the input voltages) during the first phase. Any significant current flow during this phase is just within the first voltage domain and the first and second sampling capacitors Csp and Csm are effectively connected in parallel, reducing the impact of any component mismatch. During the second phase, the sampling phase, the movement of charge in the first voltage domain is substantially just that due to the differential voltage of interest and thus may be relatively small. In the third phase, the transfer phase, the sampled charge is transferred across the boundary to the second voltage domain. This avoids the problems of a large common-mode current flowing to the ground reference domain and the associated problems of common-mode to differential conversion.

For correct sampling of the differential voltage of interest, during the sampling phase the common-mode voltage of the input signals should remain at the same level (which should be the same level that the sampling capacitors were pre-charged to), i.e. there should be no modulation of the input voltages during the second phase. Likewise, for the double sampling arrangement illustrated in FIG. 4, as the first and second sampling capacitors Csp and Csm are connected to the input voltages during the third phase (the transfer phase) to provide additional sampling, it is also beneficial to avoid any modulation of these input voltages during the third phase. It will be noted that for a single sampling configuration, if the first and second sampling capacitors Csp and Csm were disconnected from the input voltage during the transfer phase, this limitation may not apply.

Therefore, at least the second phase and, for the double sampling sensing circuit 400 illustrated in FIG. 4, both the second and third phases, should be timed so as to avoid any modulation of the input voltages, i.e. to avoid any signal edge in the PWM signal waveform at the input nodes 401p and 401m.

Whilst, in some implementations, it may be possible to vary the timing of the second and third phases of the operation of the sensing circuit based on knowledge of the PWM waveform so as to avoid transitions in the PWM waveform, this can lead to a variable sample timing for the operation of the sensing circuitry 400, which can be problematic. In embodiments of the present disclosure, the timing of switching of the output stage 103 of the switching driver is coordinated with the timing of the phases of the operation of the sensing circuitry 400. In particular, the control of the switching driver may be implemented to avoid any PWM transition at the relevant output node during a time window defined for the relevant phase(s) of the sensing circuitry 400, where the relevant time window occurs at regular intervals.

FIG. 5 illustrates this principle. FIG. 5 illustrates a timing diagram showing the timing signals φ1, φ2 and φ3 defining the first, second and third phases P1, P2 and P3 of operation of the sensing circuit. Note that the waveforms illustrated in FIG. 5 are for the purposes of explanation only and nothing should be inferred about the relative durations of the different phases. FIG. 5 illustrates that a signal NT may be used to define time windows in which transitions in the voltage OUTPP is not allowed. The time windows where no transitions in the voltage OUTPP are allowed may encompass substantially the whole duration of the second phase P2, and also a portion of the preceding phase P1, so that there is time for the voltages on the first and second sampling capacitors Csp and Csm to settle following any voltage transition in the first phase P1 before the start of the second phase P2. In other words, the window of no voltage transitions in the input voltage is control such that the signal dependent common-mode pre-charging is sufficiently settled to avoid any residual error being transferred across the boundary between voltage domains during the sample and transfer phases, which could result in error in the ground referenced domain. For the double sampling configuration of FIG. 4, the window in which transitions of OUTPP are not allowed also includes substantially the whole duration of the third phase P3. The signal NT thus defines the time windows in which a transition of OUTPP is not allowed, and consequently, the time windows in which a transition of OUTPP is permitted.

In the discussion above, the operation of the sensing circuit involves three distinct phases, including a common-mode pre-charge phase, in which the same voltage Vcm1 to be applied to both of the sampling capacitors Csp and Csm to provide pre-charging of the sampling capacitors to substantially the common-mode voltage. In some implementations, during the pre-charge phase P1 the different input voltages could instead be applied to the first and second sampling capacitors Csp and Csm, i.e. the voltage OUTPP would be applied to the first sampling capacitor Csp during both phases P1 and P2 and the voltage OUTP would be applied to the second sampling capacitor Csm during both phases P1 and P2. In this case, phases P1 and P2 are effectively combined into a single phase, with the time window in which a transition of OUTPP is not allowed extending for a significant period at the end of the combined phase to allow for settling of the common-mode voltage on the first and second sampling capacitors Csp and Csm.

The co-ordination of switching may be implemented by a modulator, such as a PWM modulator, of the switching driver. The modulator may be configured to manage transitions of edges in the OUTPP voltage away from the sampling and transfer phases of the sensing circuit, whilst retaining the target duty-cycle intact, with no meaningful impact on modulator performance observed.

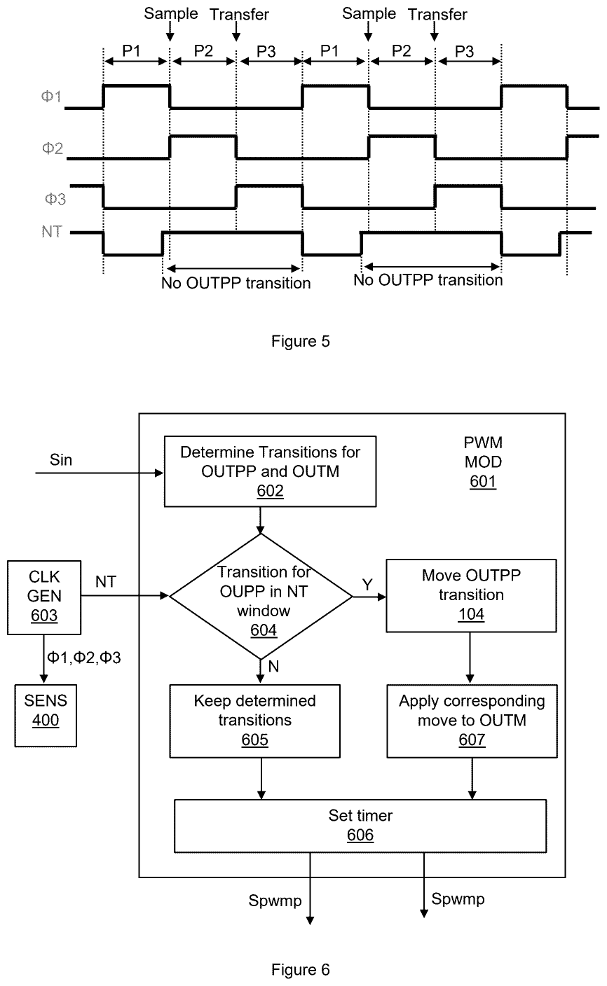

FIG. 6 illustrates one example of how the switching driver may be controlled to manage PWM edge transitions away from the sampling periods of the sensing circuitry.

FIG. 6 illustrates one example of a process flow that may be implemented by a modulator 601 of the switching driver which is configured to receive the input signal Sin and generate PWM control signals Spwmp and Spwmm for controlling the switching of the output stage 103 to modulate the voltages at the output nodes 102p and 102m respectively, i.e. the modulate the voltages OUTPP and OUTM.

The modulator is configured to receive the input signal Sin and determine (block 602) the locations, in time, when the voltage OUTPP and OUTM should transition. One skilled will be very well aware of how the timing of transitions at the output nodes of a switching driver may determined, for instance by comparing a carrier waveform with threshold values derived from the input signal (including feedback for a closed-loop switching driver).

In the example of FIG. 6, the modulator 601 is then configured to determine whether the timing of the transition in the voltage OUTPP may coincide with one of the sensitive phases of operation of the sensing circuitry 400. As noted above, this may be implemented by generating a signal NT that determines time windows in which transitions of OUTPP are not allowed. In the example of FIG. 6, a clock generator 603 may thus generate the timing signals φ1, φ2 and φ3 for controlling the phases of operation of the sensing circuitry 400 and also the corresponding NT signal which is provided to the modulator 601. Note that these timing signals may be generated as look ahead signals of what the timing of the sensing circuitry will be, to allow for appropriate synchronisation of the PWM control by the modulator.

The modulator 601 may thus determine (block 604) whether the transition in the voltage OUTPP will fall in a time window in which transitions are not allowed. If not, the modulator may keep (block 605) the originally determined timings and set (block 606) a timer to generate the switching controls signals Spwmp and Spwmm accordingly. If, however, the originally determined timing of the transition of OUTPP would fall within a time window in which transitions are not allowed, the modulator may move the location in time of the OUTPP transition. Depending on where the original time location of the transition in OUTPP falls with the time window in which transitions are not allowed, for instance whether or not the original time location of the transition in OUTPP is closer to the start or the end of the time window, the modulator 601 may either advance the timing location of the transition, e.g. to just before the start of the time window in which transitions in OUTPP are not allowed, or delay the timing location of the transition, e.g. to just after the end of the time window in which transitions are not allowed.

For the example of FIG. 6, which corresponds to a modulator for a BTL switching driver where current sensing is performed at the first output node 102p only, then there is no limitation, in terms of current sensing, on the timing location of the transition in the voltage at the second output node 102m, i.e. the transition in the OUTM voltage. The modulator is therefore configured to apply (block 607) a corresponding time shift to the timing of the OUTM transition as was determined for the OUTPP transition. Applying the same time shift to the transitions of OUTPP and OUTM can preserve the duty-cycle of the relevant differential voltage across the load, just some phase shift applied. In this case, the new timing locations for both the OUTPP and OUTM transitions are used to set the timer (block 606).

This approach thus allows the timing of the PWM switching of the output stage of the switching driver to be controlled to avoid sensitive periods for the operation of the sensing circuitry 400, whilst maintaining, as far as possible the desired duty-cycle for driving the load 101. In the event that the duty-cycle can't be preserved within a given PWM cycle, then any error in the duty-cycle could be carried forward an error for one or more subsequent cycles according to a noise shaping scheme, so as to ensure the average duty-cycle is maintained correctly. It will be understood, however, that FIG. 6 illustrates just one example of how the PWM switching could be coordinated with the sensing operation of the sensing circuitry 400 and other examples could be implemented, e.g. based on suitable look-up tables of when the transitions should occur.

In some implementations, rather than controllably adjust both the PWM transitions at both of the output nodes, i.e. to control both the OUTPP and OUTM transitions, the modulator could be implemented to only control the voltage transitions at the node at which the current is sensed, i.e. the OUTPP transitions in the examples discussed above. In this case, if both a high-to-low and a low-to-high transition of OUTPP fall outside of the time window when transitions in OUTPP are not allowed, no timing adjustment is needed. If one or both of the high-to-low and a low-to-high transition of OUTPP fall within the time window when transitions in OUTPP are not allowed, but the same time shift can be applied to both transitions to move them both outside that time window, then relevant time shift may be applied to both transitions. If however, it is not possible to apply the same time shift to both transitions, it may not be possible to maintain the desired duty-cycle in a given PWM cycle period, but the modulator may be configured to use noise shaping techniques to adjust the duty-cycle from one PWM cycle to the next to avoid the critical periods for the sensing circuitry whilst generating the desired output drive signal.

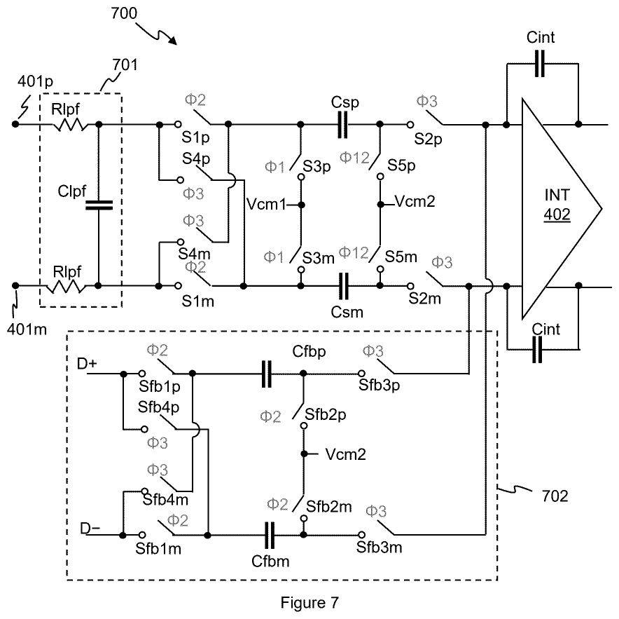

FIG. 7 illustrates sensing circuitry 700 according to an embodiment in which similar components to those discussed with respect to FIG. 4 are identified by the same reference numerals. The sensing circuit 700 of FIG. 7 is similar to the sensing circuit 400, but includes a low-pass filter 701 in the first voltage domain, implemented by filter resistors Rlpf and filter capacitance. The filter may be configured to act as an AAF. The sensing circuitry 700 can be seen as implementing a discrete-time switched-capacitor ADC with an AAF (although the AAF may be omitted in some implementations). FIG. 7 also illustrates that switches S5ap and S5bp have been combined into a single switch S5p and likewise switches S5am and S5bm have been combined into a single switch S5m. Each of the switches S5p and S5m are on for both of the first and second phases and are controlled by an appropriate timing signal ¢12.

FIG. 7 also illustrates that the sensing circuitry may comprise a switched capacitor feedback arrangement 702 which is implemented as part of the second voltage domain, e.g. the ground reference voltage domain.

The feedback arrangement is configured to received feedback signals D+ and D−, which may, for instance, be output voltages from a quantizer of the sensing circuitry (not separately illustrated) which is downstream of the integrator.

During the sampling phase, i.e. the second phase P2 defined by the timing signal φ2, the feedback signals D+ and D− may be applied to respective first electrodes of first and second feedback capacitors Cfbp and Cfbm by switches Sfb1p and Sfb1m, whilst the second electrodes of the first and second feedback capacitors Cfbp and Cfbm are connected to the second domain voltage Vcm2, i.e. the common-mode voltage for the ground referenced domain, by respective switches Sfb2p and Sfb2m.

During the transfer phase, i.e. the third phase P3 defined by the timing signal φ3, the second electrodes of first and second feedback capacitors Cfbp and Cfbm are connected to the inputs of the integrator amplifier 402 via switches Sfb3p and Sfb3m respectively.

The first feedback capacitor Cfbp is connected to the input which is connected to the second sampling capacitor Csm during the transfer phase and the second feedback capacitor Cfbm being connected to the input which is also connected to the first sampling capacitor Csp during the transfer phase. For the double sampling arrangement illustrated in the FIG. 7, during the transfer phase, i.e. the third phase P3, the first electrodes of the first and second feedback capacitors Cfbp and Cfbm are connected to the feedback signals D− and D+ respectively via respective switches Sfb4p and Sfb4m, but again it will be understood that this would not then case for a single sampling configuration.

During the sampling phase, the first and second feedback capacitors Cfbp and Cfbm are thus charged by the feedback signals, relatively to the second domain voltage Vcm2, e.g. ground. During the transfer phase the feedback capacitors are connected to the inputs of the integrator amplifier 402 to apply the feedback at the same time as the signals sensed by the first and second sampling capacitors Csp and Csm.

In the example of FIG. 7, the voltage difference between the first and second input terminals 401p and 401m, which may for instance correspond to the voltage drop across the sense resistor Rsns, is sensed directly, after filtering by the optional AAF. As noted above, this voltage drop may be relatively small. In some implementations it may be beneficial to apply some gain in the first voltage domain, i.e. to apply some gain in the floating voltage domain before transfer of the signal across the boundary to the second voltage domain, e.g. to the ground referenced domain.

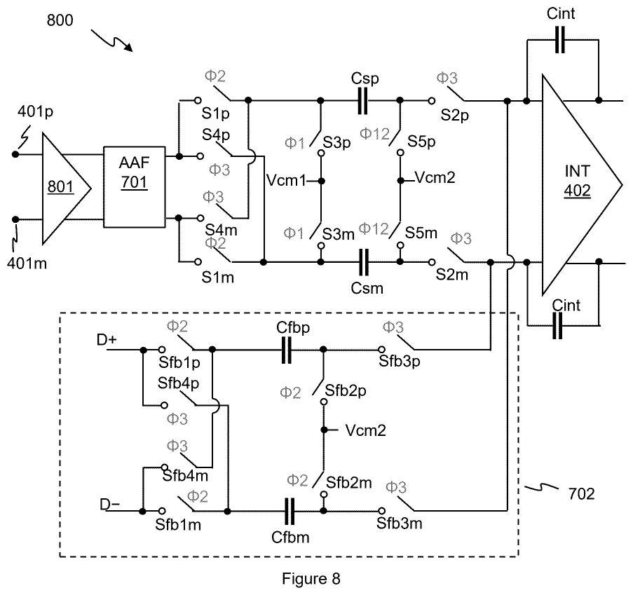

FIG. 8 illustrates another example of a sensing circuit 800. The sensing circuit 800 is similar to that described with reference to FIG. 7 and similar components are identified by the same references. The sensing circuit 800 includes a gain circuit 801, e.g. a suitable AFE which applies gain, which is configured to apply some gain in the floating domain. There are various ways in which suitable gain could be applied, as would be understood by one skilled in the art.

It will be noted that the gain circuit 801 may suffer from component mismatch issues, but as noted above the operation of the sensing circuit with the pre-charge phase and timing control of voltage transitions in the input voltage means that there is no significant common-mode current during the relevant sample and transfer periods.

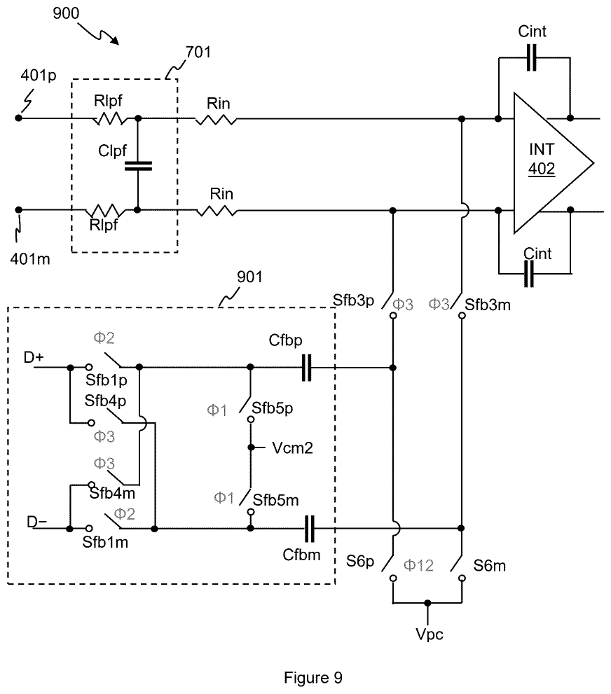

FIG. 9 illustrates a further example of a sensing circuit 900 according to an embodiment. In the example of FIG. 9, the integrator 402 is implemented as a continuous time integrator in the first voltage domain, i.e. in the floating voltage domain. The integrator 402 will thus act to provide gain in the floating voltage domain. The sensing circuit 900 thus does not include any sampling capacitors in the main forward signal path and the integrator is configured to receive the input voltage, in this example, via input resistors Rin and an optional AAF 701 The transition between the first voltage domain and the second voltage domain for the main forward signal path may be implemented downstream, e.g. in a subsequent stage of a delta-sigma ADC.

The sensing circuit 900 includes a ground referenced feedback arrangement 901 and the first and second feedback capacitors Cfbp and Cfbm of the feedback arrangement 901 act as a boundary between the first voltage domain and the second voltage domain.

The feedback arrangement 901 is operated as a switched capacitor feedback arrangement and thus operates in series of phases. In a sampling phase (which will be referred to as phase P2 for consistency with the prior discussion), the first electrodes of the first and second feedback capacitors Cfbp and Cfbm are connected to the feedback signals D+ and D− by switches Sfb1p and Sfb1m in a similar manner as discussed with reference to FIG. 7. However, during this sample phase, the second electrodes of the first and second feedback capacitors Cfbp and Cfbm are connected to a voltage Vpc via switches S6p and Som respectively. The voltage Vpc is a voltage which tracks the voltage at the virtual earth of the integrator 402, which may be generated by the sensing circuitry. During the sample phase, the first and second feedback capacitors Cfbp and Cfbm are thus charged by the feedback voltages D+ and D− with respect to this voltage Vpc.

During the transfer phase (which will be referred to as phase P3 for consistency with the prior discussion), the second electrodes of first and second feedback capacitors Cfbp and Cfbm are connected to the inputs of the integrator amplifier 402 via switches Sfb3p and Sfb3m respectively. FIG. 9 illustrates a double sampling feedback arrangement and thus, during the transfer phase the first electrodes of the and second feedback capacitors Cfbp and Cfbm are connected to the feedback signals D− and D+ respectively via respective switches Sfb4p and Sfb4m, but again it will be understood that this need not be the case.

Again, it is desirable for any voltage transitions in the sensed voltages at the input nodes 401p and 401m, e.g. in the voltages OUTPP and OUTP, do not occur during the sampling or transfer phases of the feedback arrangement, and thus the timing of the voltage transitions for OUTPP may be co-ordinated in a similar manner as discussed above. The feedback arrangement 901 may thus be operable in another mode (referred to as mode P1 for consistency with the discussion above) in which any transitions in the input voltage occur (but sufficiently far ahead of phase P2 so that the voltages have settled before the start of phase P2). In this P1 case, the first electrodes of the first and second feedback capacitors Cfbp and Cfbm may be connected to the second domain voltage Vcm2 by switches Sfb5p and Sfb5m respectively, whilst the second electrodes of the first and second feedback capacitors Cfbp and Cfbm may be connected to the voltage Vpc by switches S6p and S6m respectively.

Embodiments of the present disclosure thus provide sensing circuits for sensing a signal of interest which is superimposed on a time varying base signal, e.g. is superimposed on a PWM waveform and addresses the issues of the variation in the time varying base signal impacting on the sensing of the signal of interest. Embodiments have been described in the context of sensing of an output current in a switching driver but it will be understood that embodiments could be implemented for sensing of other signals. Embodiments have been described in the context of differential sensing, with the time variation of the base signal providing a common-mode variation, but the principles could be applied to sensing of a single ended signal (where a reference signal is available that varies with the base signal).

Embodiments therefore provide a circuit for sampling a signal, where the circuit is controlled to accommodate a transition in the sensed signal. The transition in the sensed signal may be as a result of a common-mode jump in a differential signal where the circuit being sensed undergoes a common-mode update, or as a result of a PWM level change in the circuit being sensed. The circuit preferably comprises any suitable Analog-to-Digital Converter (or ADC), e.g. a discrete-time ADC, a continuous-time ADC, a double-sampling ADC, a normal sampling ADC, etc. In addition, the circuit may be arranged to sample a single input, or multiple input signals. Preferably, the circuit is for sampling a current level.

Embodiments provide a circuit for sampling a signal, wherein the circuit is controlled to have: a pre-charge phase wherein a circuit generating the signal to be sensed undergoes a transition or a common mode update, and a sampling and conversion phase wherein the sensed signal is sampled and converted by the circuit. Preferably, the pre-charge phase allows for charging elements of the circuit to a common mode, a transition level, or a reference level of the sensed signal. Preferably, no sampling or conversion of the sensed signal is performed in the pre-charge phase, such that only the relatively small-scale modulating signal component of the sensed signal is captured in the sampling and conversion phase. Alternatively, for some implementations, it will be understood some initial sampling of the signal may overlap with the pre-charge phase.

The circuit may be coupled with a switching power stage, the circuit being arranged to sense a signal of a switching power stage, wherein control of the sensing circuit is coordinated with the switching of the switching power stage such that any common mode or PWM transitions of the sensed signal occur in the pre-charge phase of the circuit.

Embodiments provide a system comprising: a switching converter, having a modulator to control switching of the switching converter according to a modulation scheme, and a sensing circuit to sense a signal of the switching converter, preferably a current, wherein the modulator of the switching converter and the sensing circuit are controlled such that the modulator defines no-transition zones for the modulation scheme, and wherein the sensing circuit sensed the signal of the switching converter when the modulator is within a defined no-transition zone.

The switching converter may be a multi-level converter (MLC) type, or may be any switching amplifier arranged to switch between different levels of output signal. The modulator and sensing circuit may be controlled such that any adjustment of modulator operation is performed while maintaining duty cycle of the implemented PWM modulator design.

Embodiments provide a circuit for sampling a signal, the circuit comprising: a first circuit portion arranged as a floating or signal-referenced circuit portion, which is not referenced to a particular ground or reference voltage, and a second circuit portion arranged as a ground-referenced circuit portion, which is referenced to a ground voltage (or to another suitable reference voltage).

By providing an initial floating portion of the sensing circuit, this allows for improved noise performance of the circuit when sampling some signal types, as the sensing circuit may be made resilient against any movement or jump in a common-mode portion of the sensed signal during operation. In addition, the design of the first portion may be made easier due to the relaxed requirements of designing a signal-referenced circuit portion.

In one implementation, a signal is initially sampled via the first signal-referenced portion before conversion to the second ground-referenced portion for output. Preferably, the circuit samples a current, preferably a current that flows between two voltage nodes or multiple nodes that have a high signal dependent common mode level. In one implementation, the current is measured through a sense resistor. Additionally or alternatively, the circuit samples a current that flows between two voltage nodes or multiple nodes that has a small differential signal modulated on a two-level or multi-level switching PWM signal.

Preferably, the circuit samples a differential current signal measured across two voltage nodes or across the terminals of a sense resistor. Preferably, the circuit comprises: a sense resistor, and an Analog-to-Digital-Converter (or ADC) coupled with the sense resistor, the ADC comprising at least one capacitor, wherein the capacitor is used as a high common-mode-blocking or DC-blocking capacitor and as an AC-coupling capacitor. The capacitor can act as the boundary between the floating portion of the circuit and the ground-referenced portion of the circuit. Preferably, the ADC generates an output based on the level of the sampled signal. Preferably, the ADC comprises a discrete-time switched-capacitor ADC, wherein at least one sampling capacitor of the ADC acts as the boundary between the first and second portions of the circuit. Alternatively, the ADC comprises a continuous-time switched-capacitor ADC, wherein at least feedback capacitor of a feedback path of the ADC acts as the boundary between the first and second portions of the circuit. Preferably, the circuit is configured such that: the first portion of the circuit comprises the sense resistor and a section of the ADC between the sense resistor and the at least one sampling capacitor (or feedback capacitor), and the second portion of the circuit comprises a section of the ADC between the at least one sampling capacitor (or feedback capacitor) and the circuit output.

Optionally, the circuit may comprise: an Analog Front End (or AFE) which may comprise a suitable analog gain stage or op amp circuitry, and/or an Anti-Aliasing Filter (or AAF), wherein the optional AFE and AAF are provided in the first portion of the circuit, between the sense resistor and the ADC.

Preferably, the circuit comprises: a switch network, and a controller to control operation of the switch network, the switch network operable in a pre-charge phase and one or more sampling phases, wherein the controller synchronizes operation of the switch network with the signal to be sampled, such that any relatively significant transitions of the signal to be sampled occur within the pre-charge phase, and such that any transients or residual errors due to such signal transitions are not sampled by the circuit during the one or more sampling phases.

Preferably, the switch network is operable in: a first phase, to pre-charge a signal voltage on the at least one sampling capacitor, a second phase, to sample the signal onto the sampling capacitor of the ADC, and a third phase, to transfer signal charge across the boundary between the first and second portions of the circuit. Preferably, the length of the pre-charge phase is chosen such that any transients due to common mode switching or signal transitions of the signal to be sensed are settled before moving to the sampling and conversion phase of the circuit.

Embodiments provide a circuit for sensing a signal, wherein the circuit defines two circuit portions, the first portion having two or more voltage reference domains, the different voltage reference domains are separated by a PWM signal in voltage, the second portion having one voltage reference domain, the circuit arranged to convert a signal sensed in the first portion into a signal in the second portion.

It should be understood—especially by those having ordinary skill in the art with the benefit of this disclosure—that the various operations described herein, particularly in connection with the figures, may be implemented by other circuitry or other hardware components. The order in which each operation of a given method is performed may be changed, and various elements of the systems illustrated herein may be added, reordered, combined, omitted, modified, etc. It is intended that this disclosure embrace all such modifications and changes and, accordingly, the above description should be regarded in an illustrative rather than a restrictive sense.

Similarly, although this disclosure makes reference to specific embodiments, certain modifications and changes can be made to those embodiments without departing from the scope and coverage of this disclosure. Moreover, any benefits, advantages, or solutions to problems that are described herein with regard to specific embodiments are not intended to be construed as a critical, required, or essential feature or element.

Further embodiments likewise, with the benefit of this disclosure, will be apparent to those having ordinary skill in the art, and such embodiments should be deemed as being encompassed herein.

As used herein, when two or more elements are referred to as “coupled” to one another, such term indicates that such two or more elements are in electrical, mechanical, or electromechanical communication, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112 (f) unless the words “means for” or “step for” are explicitly used in the particular claim.

1. A switching driver circuit comprising:
a modulator configured to control a switching output stage to modulate a first output node between different switching voltages with a controlled duty-cycle based on an input signal;
a current sensor configured to sense an output current through the first output node by sensing a voltage drop across a sense resistor connected in series with the first output node;
wherein the current sensor is operable to perform a first sensing operation during a first time window that occurs at regular intervals and the modulator is configured to control the switching output stage to avoid any transition in switching voltage at the first output node during said first time window.

2. The switching driver circuit of claim 1 wherein the current sensor comprises:
first and second sensor input nodes connected on either side of the sense resistor to receive first and second sense voltages; and
first and second sampling capacitors;
and the current sensor is configured to be operable in a sampling phase in which the first and second sampling capacitors are connected to be charged by the first and second sense voltages respectively and wherein the first time window corresponds to at least an end period of said sampling phase.

3. The switching driver circuit of claim 2 wherein the current sensor is further configured to be operable in a transfer phase in which charge sampled onto the first and second sampling capacitors during the sampling phase is configured to be transferred to an integrator.

4. The switching driver circuit of claim 3 wherein the current sensor is configured such that, during the transfer phase, the first and second sampling capacitors are connected to the second and first sense voltages respectively and wherein the first time window also comprises said transfer phase.

5. The switching driver circuit of claim 3 wherein the first and second sampling capacitors are configured to act as a boundary between a first voltage domain for sensing the first and second sense voltages and a second voltage domain for the integrator.

6. The switching driver circuit of claim 5 wherein the first voltage domain is a floating voltage domain and the second voltage domain is a static voltage domain.

7. The switching driver circuit of claim 3 wherein the current sensor is further configured to be operable in a pre-charging phase in which the first and second capacitors are each charged to a voltage indicative of a common-mode voltage of the first and second sense voltages and wherein at least part of said pre-charging phase is outside of said first time window such that a transition in switching voltage at the first output node can occur during the pre-charging phase.

8. The switching driver circuit of claim 1 wherein the current sensor comprises:
a feedback arrangement comprising first and second feedback capacitors;
the feedback arrangement being configured to be operable in a sampling phase in which the first and second feedback capacitors are connected to be charged by first and second feedback voltages and a transfer phase in which the charge sampled onto the first and second feedback capacitors during the sampling phase is configured to be transferred to an integrator;
wherein said first time window comprises at least one of said sampling and transfer phases.

9. The switching driver circuit of claim 1 wherein the modulator is configured to determine an initial timing for a voltage transition at the first output node and to determine whether said initial timing falls within said first time window and if so to apply a timing shift to said initial timing to determine a new timing for the voltage transition that falls outside the first time window.

10. The switching driver circuit of claim 9 wherein the timing shift may be either of a timing advance or a timing delay.

11. The switching driver circuit of claim 9 wherein the modulator is configured to carry any timing error arising from said timing shift in one modulator switching cycle into one or more subsequent modulator switch cycles.

12. The switching driver circuit of claim 9 wherein the modulator is further configured to control the switching output stage to modulate a second output node between different switching voltages with a controlled duty-cycle based on the input signal so as to drive a load connected between the first and second output nodes in a bridge-tied-load configuration, and wherein the modulator is configured to determine an initial timing for a voltage transition at the second output node and to apply any timing shift determined for the voltage transition at the first output node as a timing shift for the voltage transition at the second output node.

13. A sensing circuit for sensing a differential voltage between first and second sense voltages, wherein a common-mode voltage of the first and second sense voltages varies in use, the sensing circuit comprising:
a first sensing portion implemented to provide a first voltage domain which is a floating voltage domain;
a second sensing portion implemented to provide a second voltage domain which is a static voltage domain referenced to a defined reference voltage; and
at least one switched capacitor configured to provide a boundary between the first and second voltage domains and being switched to transfer charge between the first and second voltage domains.

14. The sensing circuit of claim 13 where the at least one switched capacitor is configured as a sampling capacitor that can be switched to sample at least one of the first and second sense voltages.

15. The sensing circuit of claim 14 wherein the at least one switched capacitor comprises first and second sampling capacitors, the sensing circuit being operable in:
a first phase in which the first and second sampling capacitors are each charged by a first domain voltage indicative of the common-mode voltage of the first and second sense voltages,
a second phase in which the first and second sampling capacitors are charged by the first and second sense voltages respectively; and
a third phase in which the first and second sampling capacitors are switched to transfer charge to said second sensing portion.

16. The sensing circuit of claim 13 wherein the first sensing portion comprises gain circuitry for applying gain to the first and second sense voltages.

17. The sensing circuit of claim 16 wherein the gain circuitry comprises an integrator.

18. The sensing circuit of claim 17 wherein the integrator is configured as a continuous time integrator and the sensing circuit comprise a discrete time feedback arrangement comprising said at least one switched capacitor.

19. A switching driver circuit comprising:
a modulator configured to control a switching output stage to modulate a first output node between different switching voltages with a controlled duty-cycle based on an input signal; and
an analog to digital converter configured to sample an output current through the first output node by sensing a voltage drop across a sense resistor connected in series with the first output node at defined sample periods;
wherein the modulator is configured to control the switching output stage to prevent voltage transitions at the first output node in time windows that include said sample periods.

20. The switching driver of claim 19 wherein the analog to digital converter comprises a first portion implemented in a first floating voltage domain and a second portion implemented in a second static voltage domain.
